(19) United States
(12) Patent Application Publication
(10) Pub. No.: US 2026/0035238 A1
(43) Pub. Date: Feb. 5, 2026

(54) DEVICE ENCAPSULATION USING PHYSICAL VAPOR DEPOSITION

(71) Applicant: TEXAS INSTRUMENTS INCORPORATED, Dallas, TX (US)

(72) Inventors: Keegan Martin, Encinitas, CA (US); Mark R. Kimmich, Frisco, TX (US); Scott R. Summerfelt, Garland, TX (US); Brian Goodlin, Plano, TX (US); Daniel Ruppel, Sandy, UT (US)

(21) Appl. No.: 18/790,791

(22) Filed: Jul. 31, 2024

(51) Int. Cl. B81C 1/00; B81B 7/00

(52) U.S. Cl. CPC B81C 1/00285; B81B 7/0038; B81B 2201/01; B81B 2203/0315; B81C 2201/0105; B81C 2201/013; B81C 2201/0181; B81C 2201/056

(57) ABSTRACT

A method includes forming a microelectromechanical system (MEMS) device wherein the MEMS device includes a cavity and one or more release holes extending from a surface of the MEMS device to the cavity, and sealing at least a portion of the MEMS device including the one or more release holes with a film utilizing a physical vapor deposition (PVD) process.

### TECHNICAL FIELD

The present disclosure relates to the field of electromechanical devices, such as microelectromechanical system (MEMS) devices, and methods of fabricating the same.

### BACKGROUND

Microelectromechanical system (MEMS) devices typically include integrated circuitry or other microelectronic elements along with micromechanical elements controlled by or otherwise interacting with the microelectronic elements. Such micromechanical and microelectronic elements typically have dimensions on a scale of about one millimeter (mm), e.g., microscale dimensions. The micromechanical elements can be formed utilizing photolithography, material deposition, etching and/or other fabrication processes which may be the same as or similar to those used for forming the associated microelectronic elements.

MEMS devices have many applications and thus, by way of example only, can serve as temperature sensors, pressure sensors, accelerometers, microswitches, micromirror spatial light modulators, and micro-fluidic devices. Because the micromechanical and microelectronic elements are usually sensitive, and thus may be damaged or degraded by uncontrolled exposure to their operating environments, such devices typically benefit from protective packaging.

### SUMMARY

The present disclosure describes MEMS devices and structures with protective packaging, e.g., an encapsulation layer or other seal, and methods of fabrication thereof. This summary is not an extensive overview of the disclosure. Rather, a purpose of the summary is to present some examples of the present disclosure in a simplified form as a prelude to a more detailed description that is presented later.

In some examples, a method includes forming a MEMS device, wherein the MEMS device includes a cavity and one or more release holes extending from a surface of the MEMS device to the cavity, and sealing at least a portion of the MEMS device including the one or more release holes with a film utilizing a physical vapor deposition (PVD) process.

In some other examples, a method of forming a MEMS device includes forming a first dielectric layer including a first dielectric material over a semiconductor substrate, forming a second dielectric layer over the first dielectric layer, the second dielectric layer including a different second dielectric material, and forming a third dielectric layer over the second dielectric layer, the third dielectric layer including the first dielectric material. The method further includes forming a plurality of openings in the third dielectric layer that expose the second dielectric layer, and removing the second dielectric layer, thereby forming a cavity between the first and third dielectric layers and exposing an underside of the third dielectric layer. The method still further includes forming a fourth dielectric layer over the third dielectric layer, the fourth dielectric layer including a different third dielectric material that seals the openings without depositing on one or more components exposed on the underside of the third dielectric layer.

In some additional examples, a device includes a MEMS structure, wherein the MEMS structure includes a cavity, one or more microscale features disposed in the cavity, and one or more openings extending from a surface of the MEMS structure to the cavity. The device further includes a film disposed on the MEMS structure, wherein the film includes a dielectric material, and wherein a portion of the dielectric material is disposed in the cavity of the MEMS structure and contained to a surface area opposite at least one of the one or more openings and away from the one of more microscale features.

### BRIEF DESCRIPTION OF THE DRAWINGS

FIGS. 1A and 1B are cross-sectional views of a portion of a MEMS device with an encapsulation layer formed using a chemical vapor deposition (CVD) process;

FIG. 2 is a cross-sectional view of a portion of a MEMS device with an encapsulation layer formed using a physical vapor deposition (PVD) process in accordance with one or more examples of the present disclosure;

FIGS. 3A-3G are cross-sectional views of a process flow for forming a MEMS device including an encapsulation layer formed using a PVD process in accordance with one or more examples of the present disclosure;

FIG. 4A is a cross-sectional view of a MEMS device with an encapsulation layer formed using a PVD process in accordance with one or more examples of the present disclosure;

FIG. 4B is a cross-sectional view of an image of a profile of a portion of an encapsulation layer formed with respect to a release hole using a PVD process in accordance with one or more examples of the present disclosure;

FIGS. 5A and 5B are cross-sectional views of a portion of a MEMS device with an encapsulation layer formed using a PVD process in accordance with another example of the present disclosure;

FIGS. 6A and 6B are cross-sectional views of a portion of a MEMS device with an encapsulation layer formed using a PVD process in accordance with yet another example of the present disclosure;

FIG. 7 is a flow diagram of a methodology for fabricating a MEMS device in accordance with one or more examples of the present disclosure; and

FIG. 8 is a flow diagram of a methodology for fabricating a MEMS device in accordance with one or more other examples of the present disclosure.

### DETAILED DESCRIPTION

The present disclosure is described with reference to the attached figures. The components in the figures are not drawn to scale. Instead, emphasis is placed on clearly illustrating overall features and principles of the present disclosure. Numerous specific details and relationships are set forth with reference to examples of the figures to provide an understanding of the present disclosure. The figures and examples are not meant to limit the scope of the present disclosure to such examples, and other examples are possible by way of interchanging or modifying at least some of the described or illustrated elements. Moreover, where elements of the present disclosure can be partially or fully implemented using known components, certain portions of such components that facilitate an understanding of the present disclosure are described, and detailed descriptions of other portions of such components are omitted so as not to obscure the present disclosure.

As used herein, terms such as “first” and “second” are used to arbitrarily distinguish between the elements such terms describe. Thus, these terms in the description and in the claims are not intended to indicate temporal or other prioritization of such elements. Moreover, terms such as “front,” “back,” “top,” “bottom,” “over,” “under,” “vertical,” “horizontal,” “lateral,” “down,” “up,” “upper,” “lower,” or the like, are used to refer to relative directions or positions of features in devices in view of the orientation shown in the figures. For example, “upper” or “uppermost” can refer to a feature positioned closer to the top of a page than other features. The terms so used are interchangeable under appropriate circumstances such that the examples and illustrations of the technology described herein are, for example, capable of operation in other orientations than those illustrated or otherwise described herein. In the following discussion and in the claims, the terms “including,” “includes,” “having,” “has,” “with,” or variants thereof are intended to be inclusive in a manner similar to the term “comprising,” and thus should be interpreted to mean, for example, “including, but not limited to.” Further, in some examples, the terms “about,” “approximately,” or “substantially” preceding a value mean+/−10-20 percent of the stated value. Still further, unless otherwise specified, the ordering of steps in the description and in the claims are not intended to limit sequencing of the performance of steps and thus alternate step sequencing is contemplated as appropriate.

Various structures disclosed herein can be formed using semiconductor process techniques. Layers including a variety of materials can be formed over a substrate (e.g., a semiconductor wafer), for example, using deposition techniques (e.g., chemical vapor deposition, physical vapor deposition, atomic layer deposition, spin coating, plating), thermal process techniques (e.g., oxidation, nitridation, epitaxy), and/or other suitable techniques. Similarly, some portions of the layers can be selectively removed, for example, using etching techniques (e.g., plasma (or dry) etching, wet etching), chemical mechanical planarization, and/or other suitable techniques, some of which may be combined with photolithography steps. The conductivity (or resistivity) of the substrate (or regions of the substrate) can be controlled by doping techniques using various chemical species (which may also be referred to as dopants, dopant atoms, or the like) including, but not limited to, boron, gallium, indium, arsenic, phosphorus, or antimony. Doping may be performed during the initial formation or growth of the substrate (or an epitaxial layer grown on the substrate), by ion-implantation, or other suitable doping techniques.

As mentioned, the micromechanical and microelectronic elements (e.g., microscale features) of a MEMS device may be damaged or degraded by uncontrolled exposure to their operating environments and thus typically benefit from protective packaging. In some examples, protective packaging of a MEMS device can include hermetic sealing. Hermeticity is the state of a device being encapsulated or otherwise sealed gastight, such as to keep both moisture and gases from penetrating into the device.

Some approaches for achieving hermeticity include packaging solutions such as through-silicon via (TSV) flip chip encapsulation and glass frit bonding. The cost and resulting package size of such approaches, however, are prohibitive. Other approaches utilize a wafer bonding process which requires unique back-end tooling as well as a significant package size. Still other approaches utilize a spin-on polymer which can seal openings into the interior of the MEMS device, followed by a hermetic thin film encapsulation. Such approaches, however, are expensive and require a significant number of processing steps while also introducing organics (e.g., carbon) into the interior of the MEM device which can lead to reliability issues for device elements formed on the interior.

In some examples, a wafer-level thin film encapsulation design and process integration flow is used which enables device hermeticity while reducing package size (e.g., a die area reduction up to about 40%) and providing significant cost savings. The wafer-level thin film encapsulation design and process integration flow can advantageously be performed utilizing standard cleanroom tooling, preventing the need for unique back-end tooling or other costly equipment, as mentioned above.

One approach to wafer-level thin film encapsulation can include chemical vapor deposition (CVD)-based encapsulation. CVD is a deposition process where a volatile gas precursor is passed over a heated surface of a substrate or other layer of a semiconductor device in a reaction chamber. The volatile gas precursor chemically reacts with the substrate surface to produce a thin film deposit. Unwanted by-products are also produced which are typically removed by a gas flowing through the reaction chamber. There are several forms of CVD that are distinguished based on the conditions in the reaction chamber. For example, atmospheric pressure CVD (APCVD) is CVD performed at standard atmospheric pressure (e.g., 1 atmosphere (atm) or 101,325 Pascals (Pa)), while sub-atmospheric pressure CVD (SACVD) is CVD performed at pressures below standard atmospheric pressure (e.g., about 13,300 Pa to 80,000 Pa).

Another form of CVD is plasma-enhanced CVD (PECVD) where plasma energy, rather than only thermal energy, drives the chemical reactions in the gas(es) resulting in a film on the substrate with properties that are desired. The enhanced energy enables the process to be performed at a much lower temperature than is possible with thermal CVD (e.g., APCVD, SACVD, etc.), making it a better alternative than thermal CVD for some materials.

However, it is realized herein that CVD-based encapsulation processing results in a coating of the microscale features within the interior (e.g., a cavity) of a MEMS device that is being encapsulated. Such coating even occurs for PECVD despite that the plasma does not extend into the interior of the MEMS cavity. The thickness of the coating on the interior of the cavity may be comparatively less than the thickness of the coating outside the cavity, but the coating still exists. Moreover, while the thickness of the coating may become progressively thinner farther from openings in the cavity (e.g., release holes, as will be explained further herein), the coating will still be of a measurable (non-negligible) thickness. The coating can occur even on surfaces relatively far from the openings and on any or all surfaces inside the cavity (e.g., sides, bottom, and top of cavity).

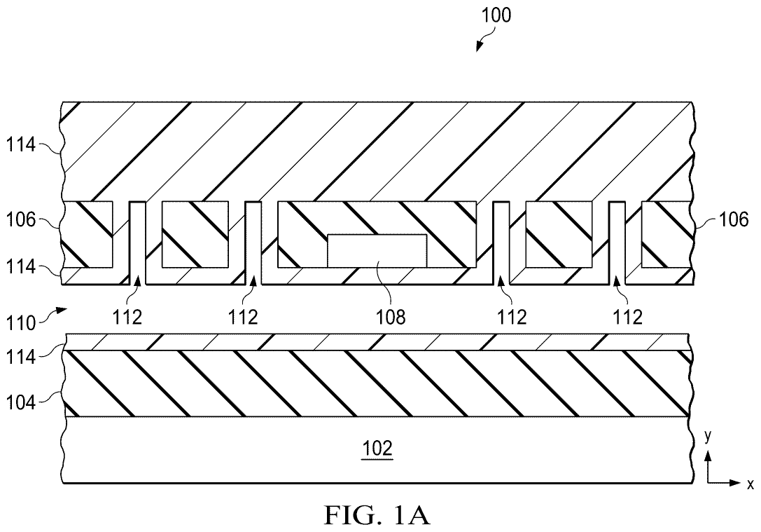

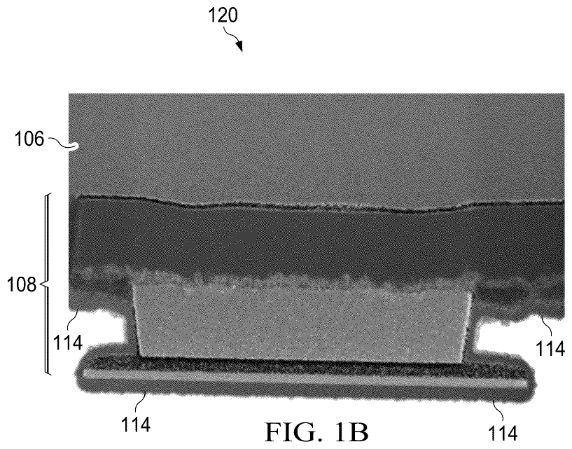

The coating that results from CVD-based encapsulation presents a significant technical issue for MEMS applications, as the microscale features inside a MEMS cavity are typically very sensitive to mass loading and contamination. For example, ohmic MEMS switches utilize metal electrodes that need to make physical contact with one another in order to provide electrical connection. CVD-based encapsulation processing coats such metallic electrodes with a dielectric material, resulting in insulating the electrodes which prohibits, or at least degrades, the electrical connection and thus the functioning of the device. While perhaps some MEMS devices can tolerate some thin level of coating in the cavity, it is realized herein that avoiding or significantly minimizing the coating formation inside the cavity is beneficial to the operation of various types of MEMS devices. The coating issue is further illustrated and described below in the context of FIGS. 1A and 1B.

FIG. 1A is a cross-sectional view of a portion of a MEMS device 100 with a thin film encapsulation layer formed using a CVD process. As shown, the MEMS device 100 includes a wafer (substrate) 102, a first dielectric layer 104 disposed on the wafer 102, a second dielectric layer 106 disposed above the first dielectric layer 104 and having a microscale feature 108 (e.g., micromechanical element and/or microelectronic element) disposed therein. The microscale feature 108 is suspended over a cavity 110 formed between the first dielectric layer 104 and the second dielectric layer 106. As will be further described below, a cavity in a MEMS device, e.g., cavity 110, can be formed by etching release holes (openings) 112 through the second dielectric layer 106 and removing a sacrificial layer (not shown) to create the cavity 110. The cavity 110 enables exposure (e.g., release) of at least one surface of the microscale feature 108 (e.g., a bottom surface in FIG. 1A). A thin film encapsulation layer 114 is formed around the MEMS device 100 (e.g., only a top portion of the thin film encapsulation layer 114 is shown formed on the second dielectric layer 106 in FIG. 1A) using a CVD process (e.g., APCVD, SACVD, PECVD, etc.).

However, the conformal deposition nature of the CVD process causes the thin film encapsulation layer 114 to form not only on the top surface of the second dielectric layer 106 and over the release holes 112 but also on the sidewalls of the release holes 112, the bottom surface of the second dielectric layer 106 including the bottom surface of the microscale feature 108 exposed during formation of the cavity 110, and the top surface of the first dielectric layer 104, as well as sidewalls of the cavity 110 (not expressly shown). While FIG. 1A is intended to be a generalized illustration of the unwanted coating problem, FIG. 1B illustrates an image 120 which is a cross-sectional view of the microscale feature 108 and the unwanted formation of a part of the thin film encapsulation layer 114 (coating) on the exposed surfaces of the microscale feature 108 in the cavity 110. Given that the operation of the MEMS device 100 may rely on a low resistance connection with the microscale feature 108, the thin film coating on any surfaces of the microscale feature 108 (resulting from the CVD process) will cause a relatively higher resistance connection, thus disrupting proper operation of the MEMS device 100.

To address the above and other technical drawbacks associated with CVD-based encapsulation, as well as other MEMS encapsulation approaches, the present disclosure describes a physical vapor deposition (PVD)-based encapsulation approach. As will be described, PVD-based encapsulation in accordance with one or more examples is less conformal (e.g., nonconformal) than CVD processing, providing advantages for wafer-level thin film encapsulation of MEMS devices. For example, as will be further described herein, PVD-based encapsulation eliminates the unwanted coating of microscale features and/or other elements and structures (components) inside the cavity of a MEMS device that is being encapsulated.

PVD is a deposition process where a solid precursor material, e.g., a dielectric material, is vaporized and deposited, within a reaction chamber, on the substrate or other layer of a semiconductor device on which the encapsulation layer is to be deposited. More particularly, in accordance with PVD, atoms of the dielectric material adhere to the substrate, forming a thin film thereon. Examples of PVD processes include, but are not limited to, evaporation and sputtering. In evaporation, the dielectric material is heated until it evaporates and then condenses as a thin film on the substrate. In sputtering, the dielectric material is ejected from a target material by bombarding the target material with high-energy ions. The ejected atoms of dielectric material then form a thin film on the substrate.

PVD dielectric materials can be incorporated in a standard clean room environment used for encapsulation processing, which enables lower cost devices. Further, by not requiring a wafer-bonding region within a die, die size reduction is achieved which further reduces cost. The use of PVD dielectric materials advantageously prevents unwanted coating of dielectric material on mechanical and/or electrical elements in a cavity of a device that is being encapsulated. By way of example only, in an ohmic MEMS switch configured to selectively control signal paths, PVD prevents the coating of metal electrodes which would otherwise prohibit or negatively impact device performance, as would occur when using CVD.

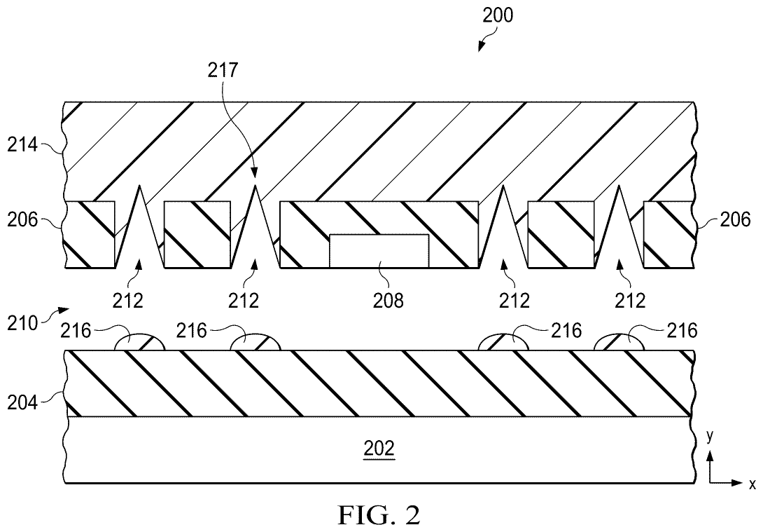

Referring now to FIG. 2, a cross-sectional view is shown of a portion of a MEMS device 200 with an encapsulation layer formed using a PVD process in accordance with one or more examples of the present disclosure. As shown, the MEMS device 200 includes a wafer (substrate) 202, a first dielectric layer 204 disposed on the wafer 202, a second dielectric layer 206 disposed above the first dielectric layer 204 and having a microscale feature 208 (e.g., mechanical element and/or electrical element) disposed therein. The microscale feature 208 is suspended over a cavity 210 formed between the first dielectric layer 204 and the second dielectric layer 206. As will be further described below, a cavity in a MEMS device, e.g., cavity 210, can be formed by etching release holes (openings) 212 through the second dielectric layer 206 and removing a sacrificial layer (not shown) to create the cavity 210. The cavity 210 enables exposure (e.g., release) of at least one surface of the microscale feature 208 (e.g., a bottom surface in FIG. 2). A thin film encapsulation layer 214 is then formed around the MEMS device 200 (e.g., only a top portion of the thin film encapsulation layer 214 is shown formed on the second dielectric layer 206 in FIG. 2) using a PVD process.

While the conformal deposition nature of a CVD process (FIG. 1A) causes a thin film encapsulation layer to coat interior features or elements inside the cavity of the MEMS device causing device operation problems, the less conformal PVD process used to form the thin film encapsulation layer 214 avoids such an unwanted coating and results in the formation of islands of dielectric material 216 on a top surface of the first dielectric layer 204 opposite the release holes 212, as shown in FIG. 2. The islands of dielectric material 216 are contained within safe zones and do not coat regions of the cavity 210 other than the top surface area of the first dielectric layer 204 opposite the release holes 212. In some examples, a safe zone may be equal to or slightly larger than the width of the corresponding release hole 212. By way of example, as shown in the figures, a height attribute of a given component, structure, or element (e.g., relatively thick, relatively thin, and/or some specific value) corresponds to a y-dimension of an x-y axis, while a width attribute of a given component, structure, or element (e.g., relatively narrow, relatively wide, and/or some specific value) corresponds to an x-dimension of the x-y axis.

In some instances, a relatively small number of atoms of the dielectric material used to form the thin film encapsulation layer 214 may not adhere and may bounce from the top surface of the first dielectric layer 204 or another surface. These atoms may create a negligibly thin and narrow deposit (e.g., thin in height and narrow in width in comparison to the islands of dielectric material 216, but not otherwise expressly shown) on a part of the bottom surface of the second dielectric layer 206 or another surface. However, such a negligibly thin and narrow deposit is contained to a point on the bottom surface of the second dielectric layer 206 within a line-of-sight from the point on the top surface of the first dielectric layer 204 from which any atoms initially collided and then bounced.

Therefore, advantageously, formation of the thin film encapsulation layer 214 using a PVD process does not coat the bottom surface of the second dielectric layer 206, including the exposed surface of the microscale feature 208, nor the top surface of the first dielectric layer 204 (notwithstanding, in some instances, the above-mentioned negligible deposit of a small number of atoms of dielectric material on the bottom surface of the second dielectric layer 206).

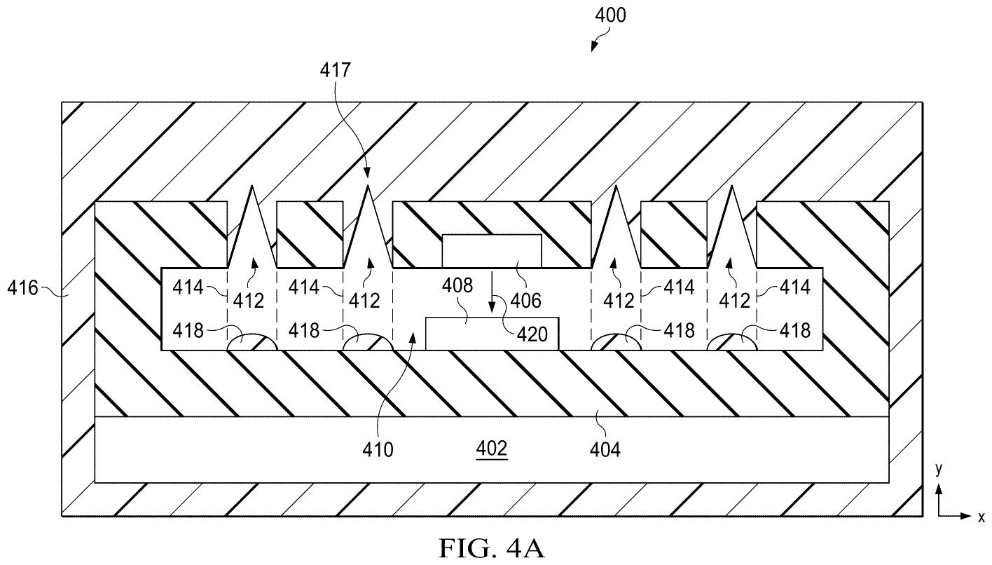

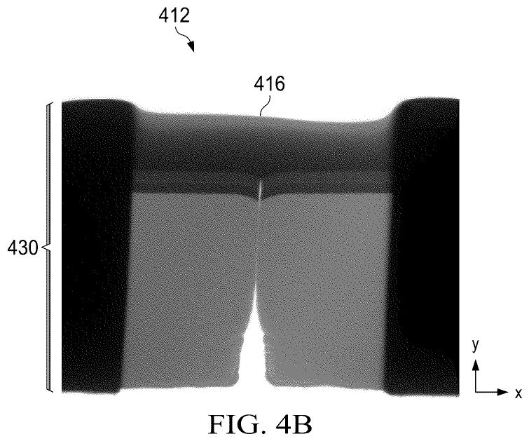

As further illustrated in FIG. 2, the thin film encapsulation layer 214 also coats the sidewalls of the release holes 212 such that the dielectric material is thicker at the top of each release hole 212 compared to the bottom of each release hole 212. Accordingly, a pinch-off opening 217 is formed within the dielectric material, which can be caused by a bread loafing effect (see also, e.g., FIG. 4B described below). The pinch-off opening 217 extends from the cavity 210 and may extend above the top surface of the second dielectric layer 206 as shown in FIG. 2. Pinch-off opening 217 is illustrated as having a substantially triangular profile coming to a point above the top surface of the second dielectric layer 206 and terminating within the thin film encapsulation layer 214. However, in some alternative examples, pinch-off opening 217 can have a substantially parabolic profile or other profile (not expressly shown). Regardless of the particular profile, pinch-off opening 217 terminates within the thin film encapsulation layer 214 and thus seals the cavity 210.

While not expressly shown in FIG. 2 or subsequent figures, in some examples, one or more additional layers (e.g., of dielectric material or otherwise) may be formed over the thin film encapsulation layer 214. Also, in some examples, the thin film encapsulation layer 214, itself, can be composed of one or more separate dielectric layers. The thin film encapsulation layer 214 enables other processing and packaging to be done with respect to MEMS device 200 while not impacting the cavity 210 other than in terms of the thermal budget of such processing and packaging. Advantageously, the thin film encapsulation layer 214, alone or with one or more other layers, creates a hermetic barrier (seal) to the cavity 210. A hermetic barrier serves to prevent moisture and other gases (e.g., hydrogen and helium) from penetrating into the cavity 210 of the MEMS device 200.

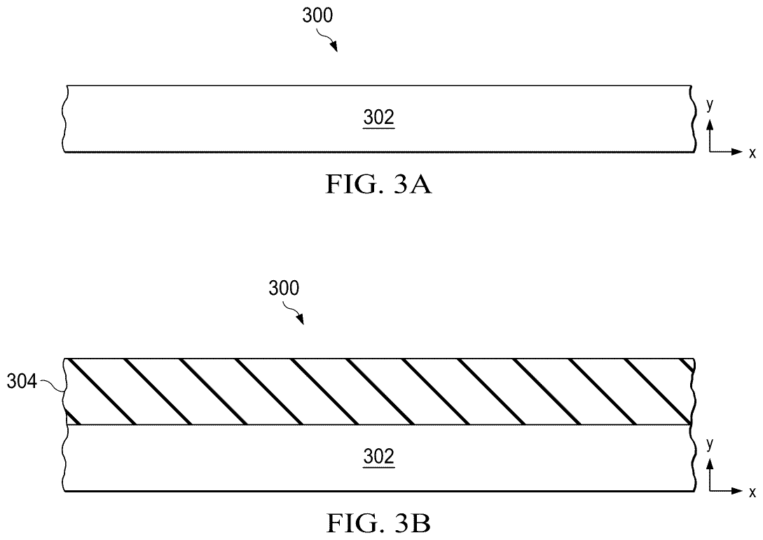

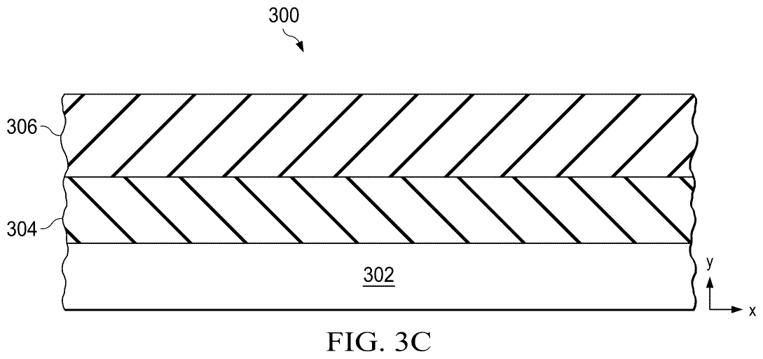

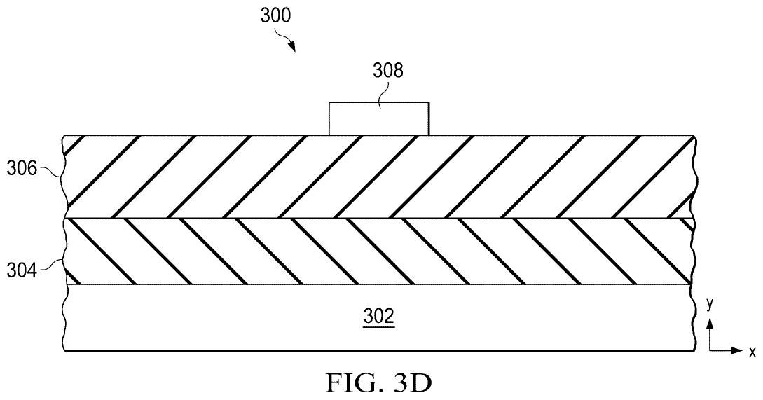

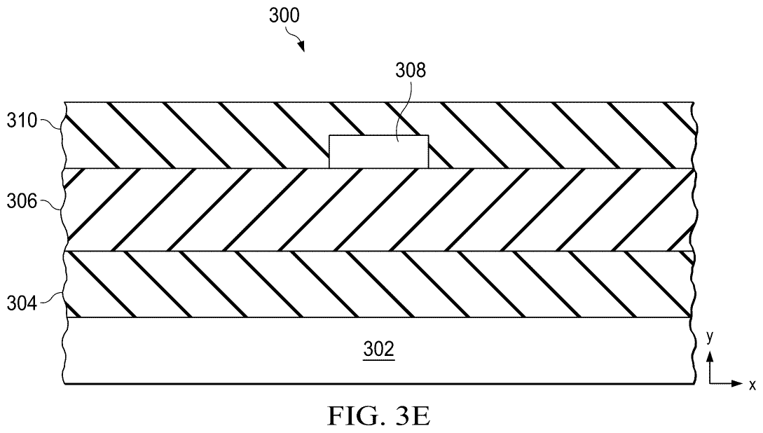

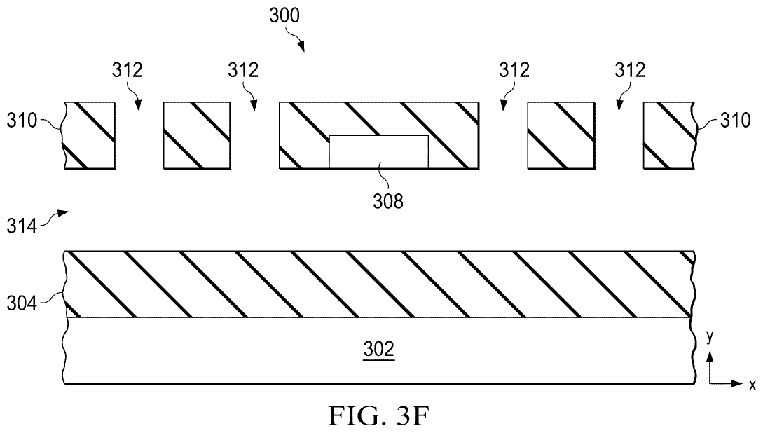

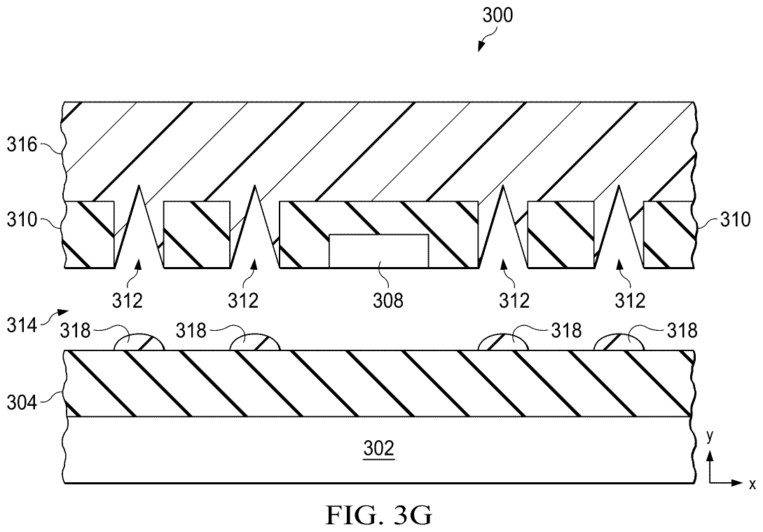

In accordance with one example, a process flow for forming a structure, such as MEMS device 200, will now be described in the context of FIGS. 3A-3G.

More particularly, FIGS. 3A-3G are cross-sectional views of a process flow for forming a structure 300 (e.g., MEMS device 200) including an encapsulation layer using PVD processing in accordance with one or more examples of the present disclosure.

As shown, the structure 300 includes a wafer 302 (FIG. 3A) with a first dielectric layer 304 deposited thereon (FIG. 3B). In some examples, the first dielectric layer 304 is formed of silicon dioxide (SiO₂) or another suitable dielectric oxide material (e.g., an interlevel dielectric (ILD) material). A nitride layer 306 is then deposited on the first dielectric layer 304 (FIG. 3C). In some examples, the nitride layer 306 is formed of silicon nitride (SiN) or another suitable nitride material and serves as a removable or sacrificial layer (FIG. 3F). A microscale feature 308 is then formed (e.g., deposited and patterned) on the nitride layer 306 (FIG. 3D). In some examples, the microscale feature 308 may include a metal stack including one or more metal layers providing one or more electrical and/or mechanical elements for a MEMS device.

A second dielectric layer 310 is then deposited over the nitride layer 306 and the microscale feature 308 (FIG. 3E). In some examples, the second dielectric layer 310 may be formed of the same or similar material as the first dielectric layer 304 (e.g., SiO₂). However, in other examples, the first dielectric layer 304 and the second dielectric layer 310 can be formed of different materials. In some examples, the second dielectric layer 310 is formed as a tensile film as this ensures that the material will not warp (or will not significantly warp) after exposure/release of the microscale feature 308, as will be further described below.

While the sacrificial layer described above (e.g., nitride layer 306) is formed using SiN, in alternative examples, other materials can be used. For example, the sacrificial layer may alternatively be formed using SiO₂ which can be removed using a wet fluorine-containing solution or a dry process using vapor hydrogen fluoride (HF). By way of example, the removable SiO₂ material may be used in complementary metal oxide semiconductor (CMOS) MEMS devices. Other materials for the sacrificial layer can include polymers (e.g., formed with an oxygen reaction using ozone or plasma enhancements), and graphite or another hard carbon source. Conductive materials can also be used for the sacrificial layer such as tungsten (W) with a wet or dry etch removal process, aluminum (Al) with a wet etch removal process, or silicon (Si) including amorphous, poly-Si, or single crystal Si. The material used for the sacrificial layer depends on the type of MEMS device being fabricated, the layout plans, and/or the desired removal processes.

Referring now to FIG. 3F, a plurality of release holes (openings) 312 are etched in the second dielectric layer 310. By way of example only, the release holes 312 may have a diameter (width) in the range of about 0.1 micrometers (μm) to 1 μm. As shown, the etching of the release holes 312 lands on the nitride layer 306. The nitride layer 306 is then etched. In some examples, the nitride layer 306 is SiN, and a tetrafluoromethane and oxygen (CF₄+O₂) plasma etch process is used to remove the nitride layer 306. This etch process may also etch SiO₂ (e.g., the material of the second dielectric layer 310), but at a negligible rate as compared to SiN. The etch and removal of the nitride layer 306 results in formation of a cavity 314 in the structure 300.

Referring now to FIG. 3G, a thin film encapsulation process that utilizes PVD is performed to form a dielectric thin film 316 (thin film encapsulation layer) over the top of the second dielectric layer 310 including the release holes 312. The dielectric thin film 316 can be formed around the entirety of the structure 300 (not expressly shown).

The amount of dielectric material, in terms of thickness (e.g., y-dimension), deposited to seal a release hole 312 using the PVD process is correlated to the width of the release hole 312. For example, the thickness of the dielectric thin film 316 can be 1× to 5× the width of the release hole 312, with one example being 2× to 3× the width of the release hole 312. In some examples, the PVD process can be tuned to optimize the release hole filling process. For example, the more off-axis atoms that can be created during the PVD process, the thinner the thin film encapsulation layer can be. In one example, the PVD process can be applied on a tilted wafer.

In some examples, the dielectric thin film 316 may be formed of aluminum nitride (AlN), silicon oxynitride (SiON), etc. In some other examples, multiple layers of different dielectric materials may be used to form the dielectric thin film 316, e.g., a first layer may be formed using SiO₂ with one or more additional layers, such as an SiON or SiN layers, being added for hermetic protection. As further shown in FIG. 3G, the PVD processing which forms the dielectric thin film 316 also results in formation of islands of dielectric material 318 on a surface of the cavity 314 opposite the release holes 312. More particularly, the islands of dielectric material 318 are contained to a surface area of the first dielectric layer 304 opposite the release holes 312 (safe zones) and do not coat regions of the cavity 314 away from the release holes 312. In some examples, the islands of dielectric material 318 have the same width as the release holes 312. In other examples, the islands of dielectric material 318 may be narrower or wider than the release holes 312.

As shown in FIG. 3G, the dielectric material of the dielectric thin film 316 is thickest in the region above or near the top of each release hole 312 but then decreases rapidly as the dielectric material forms farther down in the release hole 312 (e.g., forming a pinch-off opening as described above in the context of FIG. 2). Also, as mentioned above, some negligible amount of atoms of the dielectric material may bounce and deposit inside the cavity 314.

Referring now to FIG. 4A, a MEMS device 400 is shown that, in some examples, can be formed utilizing a process that is the same or similar to the process flow of FIGS. 3A-3G. MEMS device 400 includes a wafer 402, a dielectric layer 404 disposed on the wafer 402, and a plurality of microscale features 406 and 408 disposed partially in and/or on the dielectric layer 404 (e.g., the dielectric layer 404 can be formed as a combination of the first dielectric layer 304 and the second dielectric layer 310 in the structure 300 of FIGS. 3A-3G)

A cavity 410 is disposed within the dielectric layer 404 exposing portions of the microscale features 406 and 408. The dielectric layer 404 further includes a plurality of release holes 412 which are associated with respective safe zones 414. The safe zones 414 represent regions of the inner surface of the cavity 410 where it is permissible for a PVD dielectric material to be formed during a thin film encapsulation processing that hermetically seals the release holes 412. The dielectric layer 404 is shown following an undercut release etch (e.g., removal of a sacrificial material, such as a nitride, not expressly shown) that forms the cavity 410.

Further, MEMS device 400 is shown following a thin film encapsulation processing where PVD processing is used to form a dielectric thin film 416 over the entirety of the dielectric layer 404 including the release holes 412. The dielectric thin film 416 may be formed of AlN, SiON, etc. The dielectric thin film 416 seals the release holes 412 in the dielectric layer 404 with minimal deposition of dielectric material in the cavity 410, e.g., islands of dielectric material 418 are formed on the surface of the cavity 410 opposite the release holes 412 within the safe zones 414 as illustrated. Pinch-off openings 417, similar to the pinch-off openings 217 described above in the context of FIG. 2, are formed in the dielectric thin film 416 as shown in FIG. 4.

The cavity 410 can be formed to expose all or portions of the microscale features 406 and 408 which, similar to the microscale feature 308, may include metal stacks including one or more metal layers providing one or more electrical and/or mechanical features of a MEMS device. By way of example only, the microscale features 406 and 408 can be respective switch contacts of an ohmic microswitch where an actuation signal applied to MEMS device 400 causes the microscale feature 406 to move in the direction of arrow 420 toward the microscale feature 408 to make physical contact therewith. Such physical contact between the microscale features 406 and 408 forms a low resistance electrical connection therebetween.

In some examples, when the MEMS device 400 is configured as an ohmic microswitch, a low resistance electrical connection can be controlled between an input terminal (not expressly shown) connected to the microscale feature 406 and an output terminal (not expressly shown) connected to the microscale feature 408. For example, in response to the presence of the above-mentioned actuation signal, the ohmic microswitch is in a closed state when the microscale feature 406 and the microscale feature 408 are in physical contact with each other and thus electrically connecting the input terminal to the output terminal. The closed state enables a signal (e.g., a radio frequency (RF) signal or any type of data or control signal) present on the input terminal to propagate to the output terminal. Then, in response to the absence of the above-mentioned actuation signal, the ohmic microswitch is in an opened state when the microscale feature 406 and the microscale feature 408 are not in physical contact with each other and thus electrically isolating the input terminal from the output terminal such that no signal can pass therethrough.

Assume that the dielectric thin film 416 is alternatively formed using CVD, as described above in the context of FIG. 1A, rather than using PVD in accordance with examples the present disclosure. If such a scenario, the microscale feature 406 and the microscale feature 408 would have a coating of dielectric material formed thereon which would prevent the low resistance electrical connection between the microscale feature 406 and the microscale feature 408. Such an unwanted coating would prevent a suitable connection between the input terminal and the output terminal of the MEMS device 400. However, by using PVD to form the dielectric thin film 416, dielectric material is advantageously limited to the safe zones 414 in the form of the islands of dielectric material 418, which are safely away from the microscale feature 406 and the microscale feature 408 and thus do not present connection issues therebetween.

In some other examples, MEMS device 400 can include one or more micro-fluidic components wherein a metal component contacts directly with a fluid during operation. The thin film encapsulation methods using PVD, as described herein, can be applied in such examples to ensure that the metal component maintains a clean surface for contact with the fluid.

In some examples, the release holes 412 have a diameter of about 0.7 micrometers (μm). Also, while the release holes 412 are generally illustrated as being of equal diameter in FIG. 4A, one or more of the release holes 412 can be a different diameter than one or more other release holes 412. Accordingly, the corresponding width dimensions of the safe zones 414 and thus of the islands of dielectric material 418 can differ from release hole to release hole.

Various examples of properties of the dielectric thin film 416 will now be described. The same or similar properties may apply to thin film encapsulation layer 214 (FIG. 2) and dielectric thin film 316 (FIG. 3G).

The dielectric constant (k) of the dielectric thin film 416 can be selected to prevent electrical shorts from occurring between bond pads and/or other structures of a MEMS device. In some examples, k is equal to or greater than 3.

With PVD, in some examples, a profile of the dielectric thin film 416 has minimal deposition into the cavity 410 due to the occurrence of a bread loafing effect, e.g., pinch-off at an opening in a surface being covered by the thin film which leaves a seam along the centerline (e.g., see profiles of pinch-off openings 217 and 417). Bread loafing occurs based on the nonconformal deposition nature of PVD. For example, bread loafing may advantageously occur near, above and/or in the release holes 412, e.g., due to a higher growth rate of the dielectric thin film 416 near, above and/or in the release holes 412 as compared to elsewhere on the surface of dielectric layer 404. FIG. 4B illustrates an example image of a bread loaf profile 430 (e.g., nonconformal contour) within one of the release holes 412. The example shown in FIG. 4B does not illustrate the seam or pinch-off opening extending above the release hole 412. As a result of the bread loafing near, above and/or in the release holes 412, minimal deposition into the cavity 410 results in the form of the islands of dielectric material 418 described above. The thickness of the dielectric thin film 416 is sufficient to seal the release holes 412 and, in some examples, may be about 2.5 μm or approximately 3× the release hole diameter. The thickness of the dielectric thin film 416 tapers off rapidly beyond the release hole diameter above the film but, in some examples, does not fall below a measurable 5-10 atom thickness or 6× or 8× the release hole diameter. In some examples, the islands of dielectric material 418 can have a thickness of about 2× the release hole diameter.

The dielectric thin film 416 can be stressed to minimize warping when the microscale feature 406 moves toward microscale feature 408 in response to the actuation signal, as described above. In some examples, the stress of the dielectric thin film 416 is about-100 MegaPascals (MPa), or in an approximate range of +150 MPa (compressive) to −150 MPa (tensile).

In some examples, the deposition temperature of the PVD process used to form the dielectric thin film 416 is minimized to prevent damage to the microscale features and/or other components, structures or elements formed in the cavity 410. In some examples, the deposition temperature is maintained at or below about 200 degrees Celsius (C). The deposition pressure of the PVD process used to form the dielectric thin film 416 is also minimized enabling a lower resulting pressure inside the cavity 410. In some examples, the deposition pressure is maintained in about the millitorr (mTorr) range (1 mTorr equals 0.133322 Pa). Advantageously, following formation of the dielectric thin film 416 using PVD, there are no (or negligible) resulting organic gases or byproduct gases, e.g., carbon, in the cavity 410 that would adversely affect the microscale features or the like.

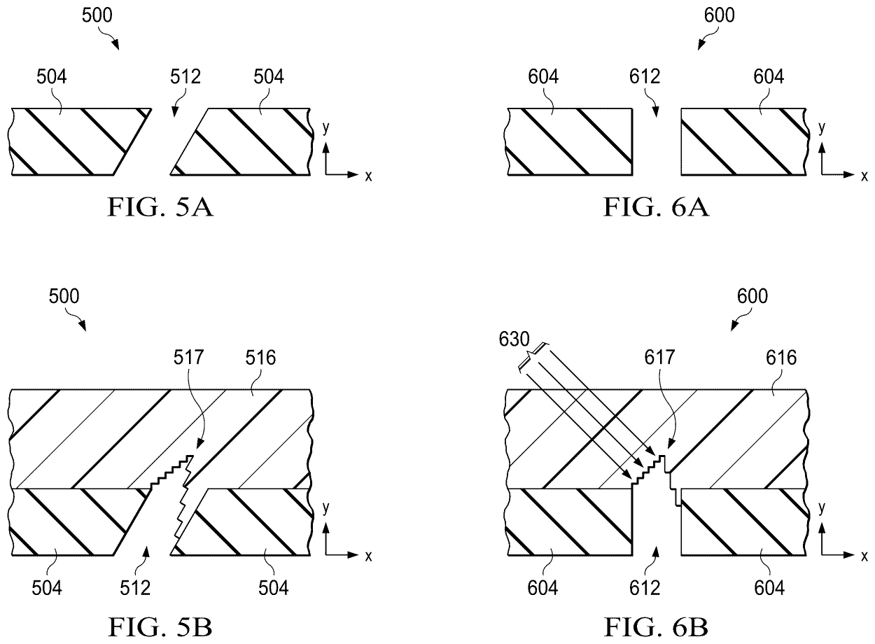

Referring now to FIGS. 5A and 5B, cross-sectional views are shown of a portion of a MEMS device 500 with an encapsulation layer formed using a PVD process in accordance with another example of the present disclosure. MEMS device 500 can be considered an alternative example of the MEMS devices of FIGS. 2, 3G, and 4A, with one or more angled release holes 512 formed in a dielectric layer 504 (e.g., a dielectric layer the same or similar to dielectric layers 206, 310, or 404) as shown in FIG. 5A.

In some examples, the one or more angled release holes 512 are formed using an angled etch process such as an angled ion mill process or one or more other angled etch processes. Thus, the angled release holes 512 have an axis that forms an angle with respect to a top surface of an underlying semiconductor substrate (e.g., the wafer 202) that is less than 90 degrees, or other than normal to the top surface. The angle of each release hole 512 can be selected based on the type of MEMs device being fabricated or some other design considerations. In some examples, one or more release holes 512 can have a different angle than one or more other release holes 512 while, in other examples, each of the release holes 512 can have the same angle. The angle of each release hole 512 can be measured with respect to a top surface or a bottom surface of the dielectric layer 504. Also, while not expressly shown, a cavity of the MEMS device 500 (e.g., similar to cavities 210, 314, or 410) is understood to be below the bottom surface of the dielectric layer 504 (e.g., underneath the dielectric layer 504 at the bottom of each of FIGS. 5A and 5B).

As shown in FIG. 5B, a dielectric thin film 516 (encapsulation layer) is deposited using a PVD process over the top surface of the dielectric layer 504 and over the one or more release holes 512. Dielectric thin film 516 can be formed similar to the thin film encapsulation layer 214, the dielectric thin film 316, or the dielectric thin film 416. An asymmetric accumulation of PVD dielectric material near, above, and/or in the release hole 512 (e.g., the accumulated PVD dielectric material can be angled or non-angled) results in a pinch-off opening 517. The asymmetric accumulation results in greater accumulation of the PVD dielectric material on one side of the release hole 512 and lesser accumulation of the PVD dielectric material on an opposite side of the release hole 512. Pinch-off opening 517 can occur for similar reasons as described above with respect to pinch-off opening 217 or 417 (e.g., bread loading effect).

FIGS. 6A and 6B are cross-sectional views of a portion of a MEMS device 600 with an encapsulation layer formed using a PVD process in accordance with yet another example of the present disclosure. MEMS device 600 can be considered an alternative example of the MEMS device 500 of FIGS. 5A and 5B with one or more release holes 612 formed in a dielectric layer 604 (e.g., a dielectric layer the same or similar to dielectric layer 504). One or more of the release holes 612, as shown in FIG. 6A, is non-angled or substantially perpendicular to a top surface or a bottom surface of the dielectric layer 604 (e.g., similar to release holes 212, 312, and 412). Also, while not expressly shown, a cavity of the MEMS device 600 (e.g., similar to cavities 210, 314, or 410) is understood to be below the bottom surface of the dielectric layer 604 (e.g., underneath the dielectric layer 604 at the bottom of each of FIGS. 6A and 6B).

A dielectric thin film 616 (encapsulation layer) is deposited using a PVD process over the top surface of the dielectric layer 604 and over the one or more release holes 612, as shown in FIG. 6B. Dielectric thin film 616 can be formed similar to the dielectric thin film 516, however, using an angled PVD fill process represented by arrows 630 in FIG. 6B. The angle of the PVD fill process can be selected based on the desired dielectric fill pattern on one or more inner sidewalls of the release hole 612. An asymmetric accumulation of PVD dielectric material near, above, and/or in the release hole 612 (e.g., the accumulated PVD dielectric material can be angled or non-angled) results in a pinch-off opening 617. Pinch-off opening 617 can occur for similar reasons as described above with respect to pinch-off opening 217 or 417 (e.g., bread loading effect).

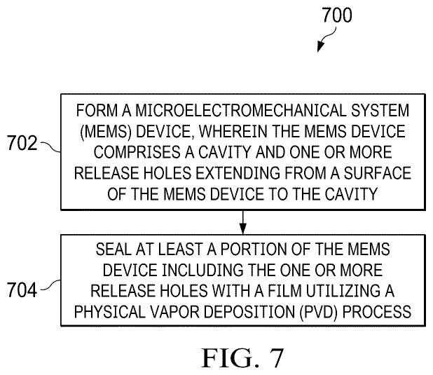

Referring now to FIG. 7, a flow diagram of a methodology 700 for fabricating a MEMS device (e.g., MEMS structures/devices 200, 300, 400, 500, and 600) in accordance with one or more examples of the present disclosure is shown. More particularly, step 702 includes forming a MEMS device, wherein the MEMS device comprises a cavity (e.g., cavities 210, 314, and 410) and one or more release holes (e.g., release holes 212, 312, 412, 512, and 612) extending from a surface of the MEMS device to the cavity. Step 704 includes sealing at least a portion of the MEMS device including the one or more release holes with a film (e.g., thin film encapsulation layer 214, dielectric thin film 316, dielectric thin film 416, dielectric thin film 516, dielectric thin film 616) utilizing a PVD process.

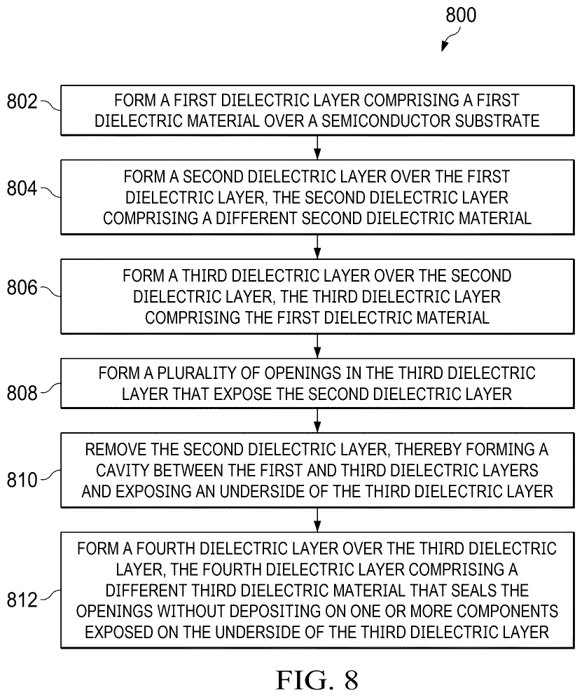

Lastly, FIG. 8 is a flow diagram of a methodology 800 for fabricating a MEMS device in accordance with one or more other examples of the present disclosure. More particularly, step 802 includes forming a first dielectric layer (e.g., first dielectric layer 304) comprising a first dielectric material (e.g., SiO₂) over a semiconductor substrate (e.g., wafer 302). Step 804 includes forming a second dielectric layer (e.g., nitride layer 306) over the first dielectric layer, the second dielectric layer comprising a different second dielectric material (e.g., SiN). Further, step 806 includes forming a third dielectric layer (e.g., second dielectric layer 310) over the second dielectric layer, the third dielectric layer comprising the first dielectric material. Step 808 includes forming a plurality of openings (e.g., release holes 312) in the third dielectric layer that expose the second dielectric layer. Step 810 includes removing the second dielectric layer, thereby forming a cavity (e.g., cavity 314) between the first and third dielectric layers and exposing an underside of the third dielectric layer. Still further, step 812 includes forming a fourth dielectric layer (e.g., dielectric thin film 316) over the third dielectric layer, the fourth dielectric layer comprising a different third dielectric material (e.g., SiON, AlN) that seals the openings without depositing on one or more components exposed on the underside of the third dielectric layer.

In addition, while in accordance with illustrated implementations, various features or components have been shown as having particular arrangements or configurations, other arrangements and configurations are possible. Moreover, aspects of the present technology described in the context of example implementations may be combined or eliminated in other implementations. Thus, the breadth and scope of the description is not limited by any of the above-described implementations.

What is claimed is:

1. A method, comprising:
forming a microelectromechanical system (MEMS) device, wherein the MEMS device comprises a cavity and one or more release holes extending from a surface of the MEMS device to the cavity; and
sealing at least a portion of the MEMS device including the one or more release holes with a film utilizing a physical vapor deposition (PVD) process.

2. The method of claim 1, wherein the film comprises a dielectric material.

3. The method of claim 2, wherein the dielectric material comprises one of aluminum nitride (AlN) and silicon oxynitride (SiON).

4. The method of claim 1, wherein forming the MEMS device further comprises:
forming a first dielectric layer on a wafer;
forming a sacrificial layer on the first dielectric layer;
forming one or more microscale features on the sacrificial layer;
forming a second dielectric layer on the sacrificial layer and the one or more microscale features; and
forming the one or more release holes through the second dielectric layer to the sacrificial layer.

5. The method of claim 4, wherein forming the MEMS device further comprises:
removing the sacrificial layer utilizing an etching process applied through the one or more release holes;
wherein the removing of the sacrificial layer forms the cavity and exposes at least a portion of the one or more microscale features in the cavity.

6. The method of claim 1, wherein the film, disposed at least one of near, above, and in the one or more release holes, has a nonconformal contour.

7. The method of claim 1, wherein the film, disposed at least one of near, above, and in the one or more release holes, has a bread loaf profile.

8. A method of forming a microelectromechanical system (MEMS) device, comprising:
forming a first dielectric layer comprising a first dielectric material over a semiconductor substrate;
forming a second dielectric layer over the first dielectric layer, the second dielectric layer comprising a different second dielectric material;
forming a third dielectric layer over the second dielectric layer, the third dielectric layer comprising the first dielectric material;
forming a plurality of openings in the third dielectric layer that expose the second dielectric layer;
removing the second dielectric layer, thereby forming a cavity between the first and third dielectric layers and exposing an underside of the third dielectric layer; and
forming a fourth dielectric layer over the third dielectric layer, the fourth dielectric layer comprising a different third dielectric material that seals the openings without depositing on one or more components exposed on the underside of the third dielectric layer.

9. The method of claim 8, wherein the third dielectric material comprises silicon oxynitride (SiON).

10. The method of claim 8, wherein the third dielectric material comprises aluminum nitride (AlN).

11. The method of claim 8, wherein the third dielectric material is deposited using physical vapor deposition.

12. The method of claim 11, wherein the physical vapor deposition includes an angled physical vapor deposition.

13. The method of claim 8, wherein forming the fourth dielectric layer includes forming a plurality of dielectric islands comprising the third dielectric material on the first dielectric layer corresponding to the plurality of openings.

14. The method of claim 8, further comprising forming a metal layer over the second dielectric layer, wherein removing the second dielectric layer exposes an underside of the metal layer, and wherein the third dielectric material seals the openings without depositing on the underside of the metal layer.

15. The method of claim 8, wherein the first dielectric material comprises silicon oxide (SiO₂) and the second dielectric material comprises silicon nitride (SIN).

16. The method of claim 8, wherein the plurality of openings in the third dielectric layer have an angle with respect to a top surface of the semiconductor substrate that is less than 90 degrees.

17. A device, comprising:
a microelectromechanical system (MEMS) structure, wherein the MEMS structure comprises a cavity, one or more microscale features disposed in the cavity, and one or more openings extending from a surface of the MEMS structure to the cavity; and
a film disposed on the MEMS structure, wherein the film comprises a dielectric material;
wherein a portion of the dielectric material is disposed in the cavity of the MEMS structure and contained to a surface area opposite at least one of the one or more openings and away from the one of more microscale features.

18. The device of claim 17, wherein the dielectric material comprises one of aluminum nitride (AlN) and silicon oxynitride (SiON).

19. The device of claim 17, wherein the one or more microscale features comprise at least one or more electrical elements and one of more mechanical elements disposed in the cavity of the MEMS structure.

20. The device of claim 17, wherein the microscale features are configured as part of an ohmic microswitch.

21. The device of claim 17, wherein the film, disposed at least one of near, above, and in the one or more openings, has a nonconformal contour.

22. The device of claim 17, wherein the film, disposed at least one of near, above, and in the one or more openings, has a bread loaf profile.

23. The device of claim 17, wherein at least a portion of the one or more openings have an angle with respect to the surface of the MEMS structure that is less than 90 degrees.

24. The device of claim 17, wherein an asymmetric accumulation of the dielectric material is disposed in at least a portion of the one or more openings.
